(19) United States
(12) Patent Application Publication
(10) Pub. No.: US 2026/0121674 A1
(43) Pub. Date: Apr. 30, 2026

(54) Apparatus, method

(71) Applicant: Intel Corporation, Santa Clara, CA (US)

(72) Inventors: Dong-Ho HAN, Beaverton, OR (US); Hagay BAREL, Kiriat Bialik (IL); Shlomi VITURI, Tel Aviv (IL); Noam KOGOS, Ramat Hasharon M (IL); Michael SHUSTERMAN, Portland, OR (US); Joy PODDAR, Bangalore (IN); Amit ZEEVI, Raanana (IL); Jun HE, Shanghai (CN)

(21) Appl. No.: 18/985,090

(22) Filed: Dec. 18, 2024

(30) Foreign Application Priority Data
Oct. 28, 2024 (WO) PCT/CN2024/127646

(51) Int. Cl. H04B 1/10; H03H 7/01

(52) U.S. Cl. CPC H04B 1/1036; H03H 7/01; H03H 2007/013; H04B 2001/1063

(57) ABSTRACT

Provided is an apparatus including interface circuitry, machine-readable instructions, and processing circuitry. The processing circuitry is configured to execute the machine-readable instructions to receive data indicating a frequency range used by a computing platform for wireless communication. The computing platform includes a notch filter for filtering platform noise from communication signals of the wireless communication. The machine-readable instructions further include instructions to search a database based on the received data. The comprises multiple frequency ranges for a respective notch filter configuration. The machine-readable instructions further include instructions to, if the database comprises a notch filter configuration for the frequency range of the received data, apply the respective notch filter configuration to the notch filter.

### BACKGROUND

Wi-Fi modules may have the capability to suppress spur and very narrow band (e.g., of a bandwidth of less than 1 MHz noises, e.g., based on a time-domain PHY digital notch filter. Typically, such notch filters may be applied to suppress self-generating noises. Furthermore, there may be applications which suppress on-die PLL (Phase-Locked Loop) noises coupled to on-die power supply rails which in turn leak to a PCB (printed circuit board).

### BRIEF DESCRIPTION OF THE FIGURES

Some examples of apparatuses and/or methods will be described in the following by way of example only, and with reference to the accompanying figures, in which

FIG. 1 illustrates a block diagram of an example of an apparatus according to the present disclosure;

FIG. 2 depicts a flowchart of a method for configuring a notch filter during runtime;

FIG. 3 depicts a flowchart of a method for generating a database according to the present disclosure;

FIG. 4 depicts a flowchart of a method for determining which notch filter configurations are relevant for a computing platform;

FIGS. 5A-5E depict an application example of the present disclosure; and

FIG. 6 illustrates more details of the present disclosure.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

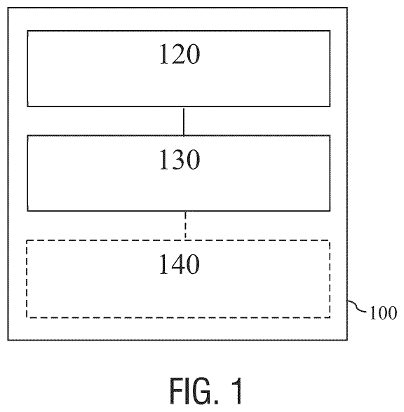

FIG. 1 illustrates a block diagram of an example of an apparatus 100 (or device 100). The apparatus 100 includes circuitry that is configured to provide the functionality of the apparatus 100. For example, the apparatus 100 of FIG. 1 includes interface circuitry 120, processing circuitry 130 and (optional) storage circuitry 140. For example, the processing circuitry 130 may be coupled with the interface circuitry 120 and optionally with the storage circuitry 140.

For example, the processing circuitry 130 may be configured to provide the functionality of the apparatus 100, in conjunction with the interface circuitry 120. For example, the interface circuitry 120 is configured to exchange information, e.g., with other components inside or outside the apparatus 100 and the storage circuitry 140. Likewise, the device 100 may include means configured to provide the functionality of the device 100.

The components of the device 100 are defined as component means, which may correspond to, or be implemented by, the respective structural components of the apparatus 100. For example, the device 100 of FIG. 1 includes means for processing 130, which may correspond to or be implemented by the processing circuitry 130, means for communicating 120, which may correspond to or be implemented by the interface circuitry 120, and (optional) means for storing information 140, which may correspond to or be implemented by the storage circuitry 140. In the following, the functionality of the device 100 is illustrated with respect to the apparatus 100. Features described in connection with the apparatus 100 may thus likewise be applied to the corresponding device 100.

In general, the functionality of the processing circuitry 130 or means for processing 130 may be implemented by the processing circuitry 130 or means for processing 130 executing machine-readable instructions. Accordingly, any feature ascribed to the processing circuitry 130 or means for processing 130 may be defined by one or more instructions of a plurality of machine-readable instructions. The apparatus 100 or device 100 may include the machine-readable instructions, e.g., within the storage circuitry 140 or means for storing information 140.

The interface circuitry 120 or means for communicating 120 may correspond to one or more inputs and/or outputs for receiving and/or transmitting information, which may be in digital (bit) values according to a specified code, within a module, between modules or between modules of different entities. For example, the interface circuitry 120 or means for communicating 120 may include circuitry configured to receive and/or transmit information.

For example, the processing circuitry 130 or means for processing 130 may be implemented using one or more processing units, one or more processing devices, any means for processing, such as a processor, a computer or a programmable hardware component being operable with accordingly adapted software. In other words, the described function of the processing circuitry 130 or means for processing 130 may as well be implemented in software, which is then executed on one or more programmable hardware components. Such hardware components may include a general-purpose processor, a Digital Signal Processor (DSP), a micro-controller, etc.

For example, the storage circuitry 140 or means for storing information 140 may include at least one element of the group of a computer readable storage medium, such as a magnetic or optical storage medium, e.g., a hard disk drive, a flash memory, Floppy-Disk, Random Access Memory (RAM), Read Only Memory (ROM), Programmable Read Only Memory (PROM), Erasable Programmable Read Only Memory (EPROM), an Electronically Erasable Programmable Read Only Memory (EEPROM), or a network storage.

The apparatus 100 may be realized as any type of computing platform, such as at least a part of a computer, e.g., as a server or multiple servers, a personal computer, a corporate computer, a smartphone, a wearable device, or the like. In more general terms, the apparatus may relate to any type of computing platform which may be capable of wireless communication, such as WLAN (wireless local area network), Wi-Fi, or the like. For example, the apparatus may comprise platform software (SW) synthesizing notch filters and interfacing with a wireless driver (a driver for a wireless communication interface) for carrying out the wireless communication.

As indicated above, the processing circuitry may implement machine-readable instructions. Such machine-readable instructions may relate to non-transitory machine-readable instructions and may be stored on the storage circuitry 140, without limiting the present disclosure in that regard.

For example, the storage circuitry 140 may include or relate to a non-transitory machine-readable medium including machine-readable instructions which, when executed on the apparatus 100, cause the apparatus 100 (or the processing circuitry 130) to carry out the functions discussed herein.

The machine-readable instructions include instructions to receive data indicating a frequency range used by a computing platform for wireless communication. The data may be any type of data in any type of data format to indicate the frequency range, such as binary data, hexadecimal data, or the like. The data may indicate the frequency by range, e.g., by directly including the frequency range (e.g., a lower frequency and an upper frequency), by referring to one or more predefined frequency range bins, or the like.

Wireless communication may refer to transmission of information over a distance without using physical connections like cables or wires. It may rely on electromagnetic waves, such as radio frequencies, microwaves, or infrared, to carry data between devices. For example, in WLAN or Wi-Fi applications, data may be transmitted using radio waves, e.g., within the 2.4 GHz and 5 GHz frequency bands (or even above 5 GHz, such as 6 GHz, or the like), without limiting the present disclosure in that regard. Such networks may enable devices like smartphones, laptops, and smart home gadgets to connect to the internet or local networks. For the transmission of data, a carrier frequency band may be used to carry a data signal, allowing information to be modulated and transmitted. Different channels (e.g., of a predetermined bandwidth, such as 20 MHZ) within such a frequency band (or frequency range) may be available to minimize interference and optimize performance. In other words, the frequency range is one of a plurality of predefined channels in one or more predefined frequency bands for the wireless communication, in some examples.

The computing platform includes or implements a notch filter for filtering platform noise from (recoverable) communication signals of the wireless communication.

A notch filter may be used to block or attenuate (i.e., to filter) specific frequencies or frequency bands to reduce interference. A notch filter may be used when unwanted signals from nearby devices or services (such as Bluetooth, cordless phones, other devices of the computing platform, or the like) overlap with one or more Wi-Fi channels. By applying a notch filter, the Wi-Fi system may filter these specific interfering frequencies while allowing the desired Wi-Fi signal to pass through, i.e., the notch filter is configured to filter the noise from the communication signal. Thereby, quality and reliability of the Wi-Fi connection may be enhanced, especially in environments with many different platforms. Notch filters may be employed in both Wi-Fi access points and client devices to enhance performance and maintain stable connectivity. Thereby, platform noise (e.g., spur noise, narrowband noise, or the like) may be filtered from the communication signals and thus, a noise-reduced (or noise-mitigated) communication signal may be obtained. Such noise may be generated by other devices of the computing platform or in vicinity to the computing platform, such as display (e.g., OLED-organic light emitting diode), an audio camera, a MIPI camera (or any other device that may require a forwarded clock).

According to the present disclosure, the notch-filter may be dynamically configurable during runtime. For example, a specific notch filter configuration may be associated with a Wi-Fi channel. Upon channel change, a different notch filter configuration may be applied. For example, the received data may indicate the respective channel. Runtime may refer to a period during which a program or application is actively executing on a computing platform (in this case, a WLAN driver). It may encompass all operations that occur from the moment the program starts until it terminates, including memory allocation, input/output handling, and other processes.

In other words, the machine-readable instructions further include instructions to search a database based on the received data. A database may relate to an (organized) collection of data that can be accessed and that comprises information in a structured format, e.g., using one or more tables, to facilitate efficient data retrieval and manipulation. For example, a mapping table may be used according to the present disclosure to associate multiple frequency ranges (of the wireless communication) with a respective notch filter configuration. In other words, the database comprises (e.g., stores) multiple frequency ranges for a respective notch filter configuration. For example, the multiple frequency ranges are predefined channels in predefined frequency bands for the wireless communication.

It should be noted that the present disclosure is not limited to a mapping table. Any type of data structuring may be applied to implement the database. For example, the database may be a relational database (e.g., an SQL database), a NoSQL database, a hierarchical database, an object oriented database, a graph database, or the like.

There may be different ways to search the database, such as on a predetermined search algorithm, such as a keyword search, a structured query language (SQL) search, a Boolean search, a range search, or the like, without limiting the present disclosure to any type of search algorithm.

If the search is successful, i.e., if the database comprises (e.g., stores) a notch filter configuration for the frequency range of the received data, the machine-readable instructions further include instructions to apply the respective notch filter configuration to the notch filter.

In some examples, the machine-readable instructions further include instructions to send the notch filter configuration to a WLAN driver of the computing platform for applying the respective notch filter configuration to the notch filter.

A WLAN driver may refer to an instance (software) that enables an operating system to communicate with a WLAN hardware device, such as a Wi-Fi adapter, to connect to wireless networks. It may manage the hardware's wireless functions, like scanning for networks, connecting, and maintaining data transmission over a WLAN protocol, such as Wi-Fi. For example, when the wireless driver receives the notch filter configuration (e.g., as a (WLAN) physical layer digital notch filter configuration), it may insert a physical (PHY) layer/level digital signal processing filter to the wireless receiver chains until the next update (change of notch filter configuration or nullifying reset) happens. For example, the notch filter may be or be based on an externally configurable WLAN PHY digital notch filter. For example, the notch filter processing/configuration may be applied to multiple antenna chains or selectively to one or a subset of antenna chains. For example, a client device may include two WLAN antennas or chains while a WLAN access point may have four to eight (or more) antennas or antenna chains. Thus, the notch filter configuration indicates to the WLAN driver to which antennas or antenna chains the notch filter configuration should be applied, in some examples.

In some examples, the machine-readable instructions further include instructions to apply the respective notch filter configuration to the notch filter during runtime of the computing platform. For example, the notch filter configuration capability may be include into the platform software (e.g., instead of in a BIOS) such that, as soon as the frequency range of the wireless communication is changed (or a channel is changed), the new notch filter configuration may be applied. Thus, it may be unnecessary to reboot the platform in order to change the configuration.

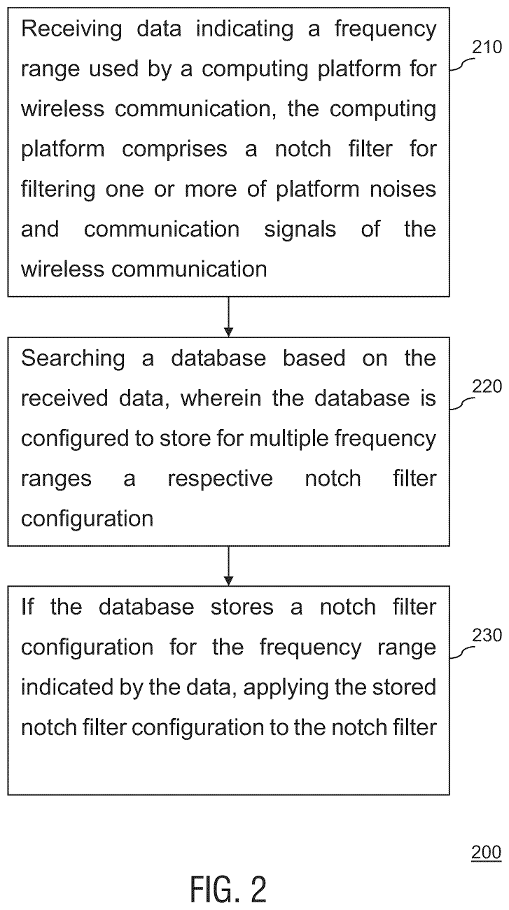

FIG. 2 depicts a flowchart of a method 200 according to the present disclosure. The method 200 may be carried out with an apparatus 100 as discussed under reference of FIG. 1.

The method 200 includes receiving, 210, data indicating a frequency range used by a computing platform for wireless communication. The computing platform includes a notch filter for filtering platform noise from communication signals of the wireless communication;

The method 200 further includes searching, 220, a database based on the received data. The database comprises (e.g., stores) multiple frequency ranges for a respective notch filter configuration.

The method 200 further includes, if the database comprises (e.g., stores) a notch filter configuration for the frequency range of the received data, applying, 230, the respective notch filter configuration to the notch filter.

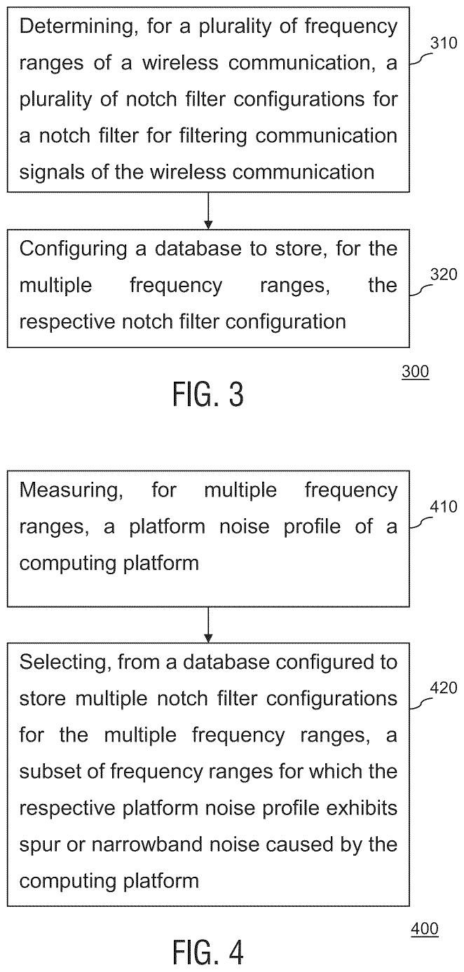

FIG. 3 depicts a flowchart of a method 300. According to the method 300, a database may be configured which comprises a plurality of notch filter configurations for multiple frequency ranges, as discussed above. The method 300 includes determining, 310, for a plurality of frequency ranges of a wireless communication, a plurality of notch filter configurations for a notch filter for filtering communication signals of the wireless communication.

For example, a platform noise measurement may be carried out and a noise profile (e.g., noise versus frequency) may be determined. To filter the noise at the measured frequency (i.e., for the measured profile), a notch filter configuration may be based on a set of notch filter coefficients of a (standard) digital filter format. Therefore, in some examples, the method further includes determining the filter coefficients.

The method 300 further includes configuring, 320, a database to comprise (e.g., to store), for the multiple frequency ranges, the respective notch filter configuration.

As indicated above, the database may be based or include a mapping table. Based on the database or mapping table, the platform may further be able to identify the needs of filtering and a desired rejection level (e.g., a degree to which unwanted frequencies or signals are attenuated or blocked).

FIG. 4 depicts a flowchart of a method 400. According to the method 400, it may be determined which notch filter configurations of a plurality of notch filter configurations can be applied to a particular computing platform. Accordingly, the method 400 includes measuring, 410, for multiple frequency ranges, a platform noise profile of a computing platform.

The method 400 further includes selecting, 420, from a database comprising (e.g., storing) multiple notch filter configurations for the multiple frequency ranges, a subset of frequency ranges for which the respective platform noise profile exhibits spur or narrowband noise caused by the computing platform.

In other words, for launching the computing platform, only those notch filter configurations are selected which are relevant for the computing platform, i.e., for which the platform noise profile exhibits spur noise or narrowband noise (without limiting the present disclosure to a certain type of noise). Thereby, only if a WLAN channel (or wireless frequency range) is used for which the computing platform exhibits a type of noise, it is necessary to select a corresponding notch filter configuration. Furthermore, less storage may be needed since not all possible noise profiles and notch filter configuration may need to be stored but only those that are relevant to the specific computing platform.

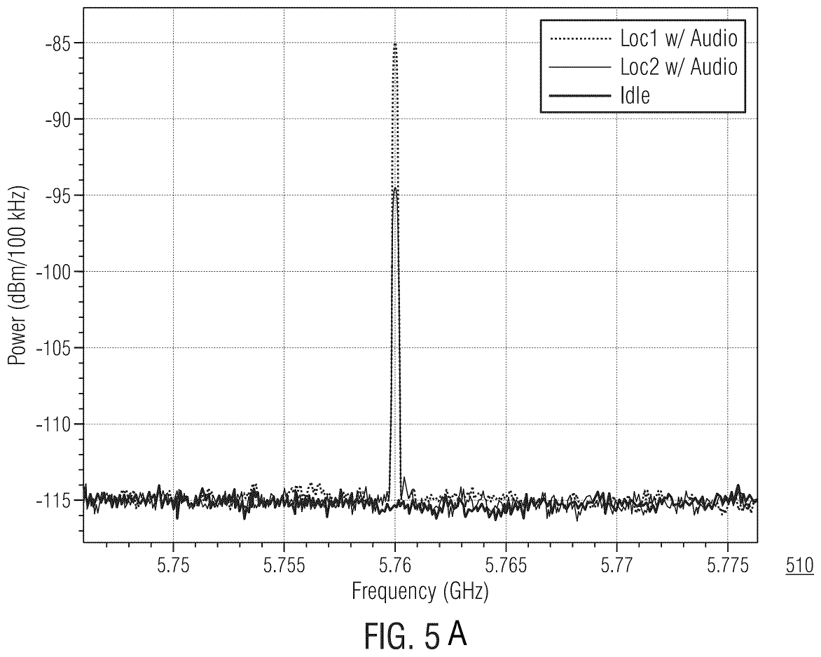

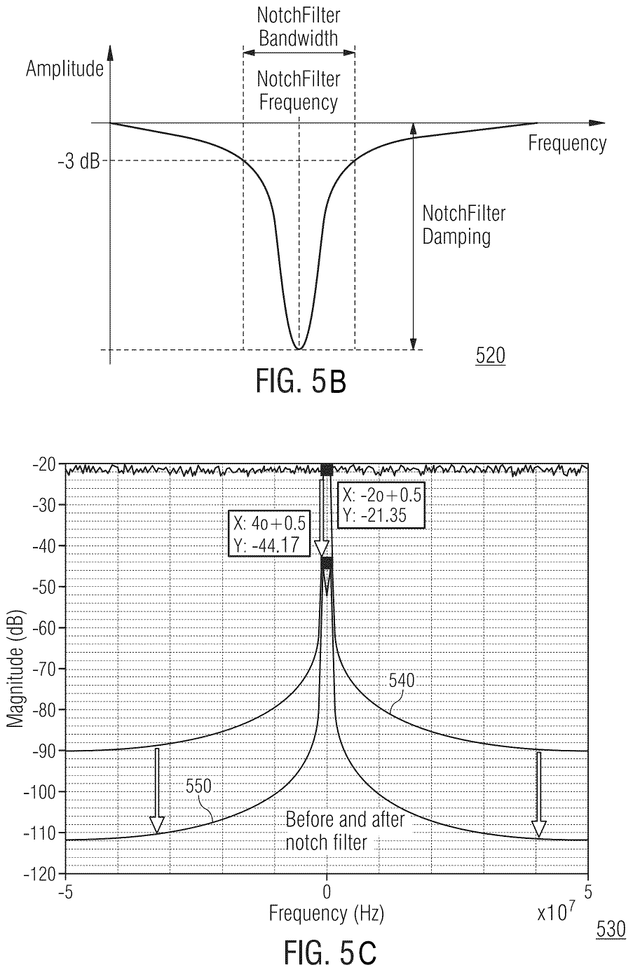

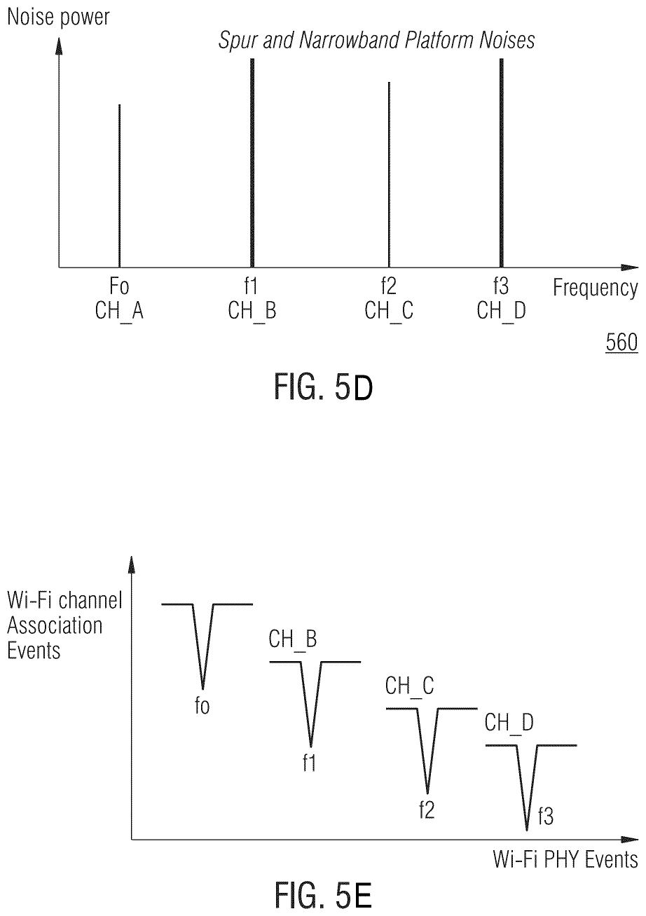

FIGS. 5A-5E depict an application example of the present disclosure. In particular, FIGS. 5A-5E depict a method how to scale a notch filter according to the present disclosure.

FIG. 5A depicts a platform noise profile 510 as a power (in dBmV/100 Hz) of a Wi-Fi signal versus a frequency (in GHz). In this example, a peak of the power arises at 5.76 GHz. In other words, FIG. 5A shows narrowband platform noise at around 5.76 GHZ.

FIG. 5B depicts a diagram 520 of frequency response of a narrowband notch filter as an amplitude (in dB) versus a frequency. The notch filter bandwidth is given by the width of the filter curve at −3 dB (without limiting the present disclosure in that regard). Furthermore, a damping effect of the notch filter is given by its (negative) amplitude.

FIG. 5C depicts a diagram 530 for illustrating a case when the notch filter is applied to the narrowband noise as a magnitude (or amplitude, in dB) versus frequency (in Hz). The noise peak is set to be zero, i.e., a normalization is carried out, but the effects depicted in FIG. 5C also apply to the noise depicted in FIG. 5A. An upper curve 540 shows the noise profile before the application of the notch filter and a lower curve 550 shows the effects of the notch filter, i.e., the noise is reduced.

FIG. 5D depicts a diagram 560 for illustrating how different spur and narrowband platform noise can be present in the same computing platform. As can be taken from FIG. 5D, different frequencies (f0, f1, f2, f3) are associated with different Wi-Fi channels (CH_A, CH_B, CH_C, CH_D). In FIG. 5D, for CH_A and CH_C, spur noise occurs at frequencies f0 and f2, respectively. Furthermore, narrowband noise occurs at frequencies f1 and f3 (i.e., for CH_B and CH_D).

As illustrated in FIG. 5E, if one of the channels CH_A to CH_D is used, a notch filter for compensating a noise at the respective frequency (f0 to f3) is applied. In other words, if a Wi-Fi cannel association event occurs for one of the channels CH_A to CH_D, a Wi-Fi PHY notch filter configuration event is triggered.

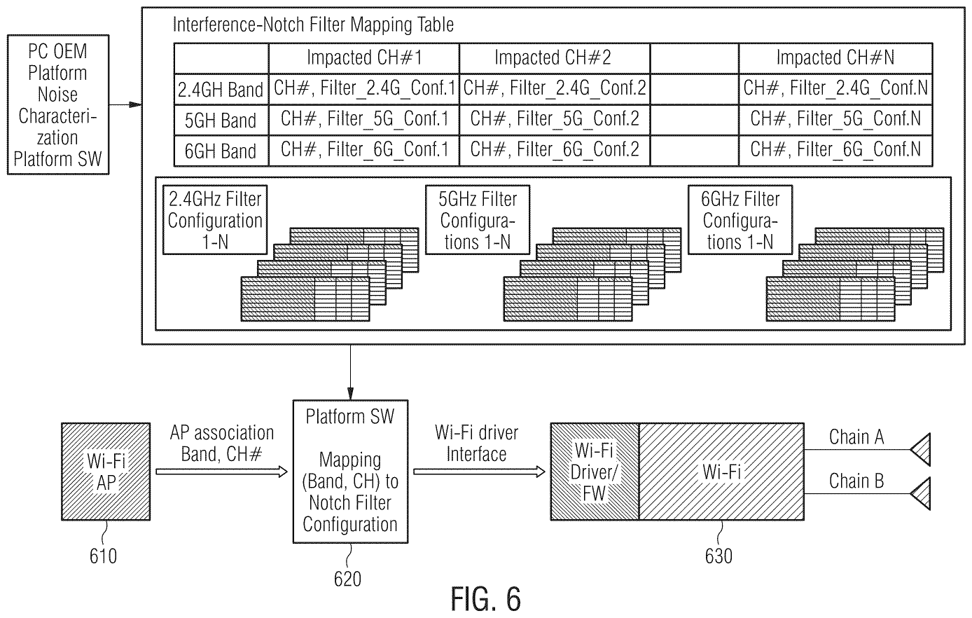

FIG. 6 illustrates more details of the present disclosure. In this example, a platform software is written and used to build a mapping table by which each platform noise is assigned to its corresponding notch filter design parameters. Thereby, a Wi-Fi PHY notch filter design capability is embedded into the platform software. Based on the mapping table, when a Wi-Fi channel listed in the table is associated, the platform software sends the notch filter design parameters to the Wi-Fi driver. Consequently, during a Wi-Fi receiver preamble detection process, the PHY digital notch filter uses the received new filter configuration until another Wi-Fi channel changes happens. In more detail, a Wi-Fi access point (AP) sends an AP association band and a channel number (CH #) to the platform software 620. The platform software 620 maps the band and the channel number to a notch filter configuration and sends it, via a Wi-Fi driver interface, to the Wi-Fi driver 630, which applies the configuration to one or more antenna chains (such as chain A or chain B in FIG. 6).

According to the present disclosure, it is not necessary to use a BIOS for implementing a notch filter since the notch filter configuration a platform software may be capable of applying the notch filter configuration upon channel change. Thereby, it may be unnecessary to carry out a reboot, if a new notch filter configuration is to be applied. Moreover, it may be unnecessary to route forwarded clock signals to inner layers of PCB or using a shielded connector and cable for suppressing noise generated based on the forwarded clock signals. It has also been recognized that such a routing-based approach may lead to higher costs. On the other hand, it may be unnecessary to use fractional PLL for a spread spectrum clocking (SSC) capability. It has been recognized that such an approach need not always work as intended, especially when the noise power spectral density is (much) higher than a thermal noise level of the platform. As an example, if spur and narrowband noise power levels are 15 dB higher than the thermal noise level, the SSC spread noises (>5 dB de-sense over 2-5 MHz span after 10 dB reduction) might be more harmful to Wi-Fi receivers than no spread cases. In audio applications, the use of SSC may even be prohibited.

Also, instead of providing a notch filter with restricted filter configurability, a dynamically configurable approach is given in the present disclosure. Such an approach may avoid increasing platform costs and may save OEMs (original equipment manufacturers) from last moment band-aided EMI shields or PCB redesigns caused by Wi-Fi certification failings.

In the following, some examples of the proposed technique are presented:

An example (e.g., example 1) relates to an apparatus comprising interface circuitry, machine-readable instructions, and processing circuitry. The processing circuitry is configured to execute the machine-readable instructions to receive data indicating a frequency range used by a computing platform for wireless communication. The computing platform includes a notch filter for filtering platform noise from communication signals of the wireless communication. The machine-readable instructions further include instructions to search a database based on the received data. The comprises multiple frequency ranges for a respective notch filter configuration. The machine-readable instructions further include instructions to, if the database comprises a notch filter configuration for the frequency range of the received data, apply the respective notch filter configuration to the notch filter.

Another example (e.g., example 2) relates to a previous example (e.g., example 1) or to any other example. In this example, the wireless communication is a wireless local area network, WLAN, communication.

Another example (e.g., example 3) relates to a previous example (e.g., example 2) or to any other example. In this example, the machine-readable instructions further include instructions to send the notch filter configuration to a WLAN driver of the computing platform for applying the respective notch filter configuration to the notch filter.

Another example (e.g., example 4) relates to a previous example (e.g., any one of examples 1 to 3) or to any other example. In this example, the frequency range is one of a plurality of predefined channels in one or more predefined frequency bands for the wireless communication.

Another example (e.g., example 5) relates to a previous example (e.g., any one of examples 1 to 4) or to any other example. In this example, the multiple frequency ranges are predefined channels in predefined frequency bands for the wireless communication.

Another example (e.g., example 6) relates to a previous example (e.g., any one of examples 1 to 5) or to any other example. In this example, the machine-readable instructions further include instructions to apply the respective notch filter configuration to the notch filter during runtime of the computing platform.

Another example (e.g., example 7) relates to a previous example (e.g., any one of examples 1 to 6) or to any other example. In this example, the respective notch filter configuration is configured to filter one or more of spur and narrowband noise caused by the computing platform.

Another example (e.g., example 8) relates to a previous example (e.g., any one of examples 1 to 7) or to any other example. In this example, the notch filter is a physical layer digital notch filter.

Another example (e.g., example 9) relates to a previous example (e.g., any one of examples 1 to 8) or to any other example. In this example, the notch filter is an externally configurable WLAN physical layer notch filter.

An example (e.g., example 10) relates to a non-transitory machine-readable medium comprising machine-readable instructions. The machine-readable instructions, when executed on an apparatus, cause the apparatus to receive data indicating a frequency range used by a computing platform for wireless communication. The computing platform includes a notch filter for filtering platform noise from communication signals of the wireless communication. The machine-readable instructions further cause the apparatus to search a database based on the received data. The database comprises multiple frequency ranges for a respective notch filter configuration. The machine-readable instructions further cause the apparatus to, if the database comprises a notch filter configuration for the frequency range of the received data, apply the respective notch filter configuration to the notch filter.

Another example (e.g., example 11) relates to a previous example (e.g., example 10) or to any other example. In this example, the wireless communication is a wireless local area network, WLAN, communication.

Another example (e.g., example 12) relates to a previous example (e.g., example 11) or to any other example. In this example, the machine-readable instructions further cause the apparatus to send the notch filter configuration to a WLAN driver of the computing platform for applying the respective notch filter configuration to the notch filter.

Another example (e.g., example 13) relates to a previous example (e.g., any one of examples 10 to 13) or to any other example. In this example, the frequency range is one of a plurality of predefined channels in one or more predefined frequency bands for the wireless communication.

Another example (e.g., example 14) relates to a previous example (e.g., any one of examples 10 to 13). In this example, the multiple frequency ranges are predefined channels in predefined frequency bands for the wireless communication.

Another example (e.g., example 15) relates to a previous example (e.g., any one of examples 10 to 14). In this example, the machine-readable instructions further cause the apparatus to apply the respective notch filter configuration to the notch filter during runtime of the computing platform.

Another example (e.g., example 16) relates to a previous example (e.g., any one of examples 10 to 15). In this example, the respective notch filter configuration is configured to filter one or more of spur and narrowband noise caused by the computing platform.

Another example (e.g., example 17) relates to a previous example (e.g., any one of examples 10 to 16). In this example, the notch filter is a physical layer digital notch filter.

Another example (e.g., example 18) relates to a previous example (e.g., any one of examples 10 to 17) or to any other example. In this example, the notch filter is an externally configurable WLAN physical layer notch filter.

An example (e.g., example 19) relates to a method. The method includes receiving data indicating a frequency range used by a computing platform for wireless communication, wherein the computing platform includes a notch filter for filtering platform noise from communication signals of the wireless communication. The method further includes searching a database based on the received data, wherein the comprises multiple frequency ranges for a respective notch filter configuration. The method further includes, if the database comprises a notch filter configuration for the frequency range of the received data, applying the respective notch filter configuration to the notch filter.

Another example (e.g., example 20) relates to a previous example (e.g., example 19). In this example, the wireless communication is a wireless local area network, WLAN, communication.

Another example (e.g., example 21) relates to a previous example (e.g., example 20). In this example, the method further includes sending the notch filter configuration to a WLAN driver of the computing platform for applying the respective notch filter configuration to the notch filter.

Another example (e.g., example 22) relates to a previous example (e.g., any one of examples 19 to 21). In this example, the frequency range is one of a plurality of predefined channels in one or more predefined frequency bands for the wireless communication.

Another example (e.g., example 23) relates to a previous example (e.g., any one of examples 19 to 22). In this example, the multiple frequency ranges are predefined channels in predefined frequency bands for the wireless communication.

Another example (e.g., example 24) relates to a previous example (e.g., any one of examples 19 to 23). In this example, the method further includes applying the respective notch filter configuration to the notch filter during runtime of the computing platform.

Another example (e.g., example 25) relates to a previous example (e.g., any one of examples 19 to 24). In this example, the respective notch filter configuration is configured to filter one or more of spur and narrowband noise caused by the computing platform.

Another example (e.g., example 26) relates to a previous example (e.g., any one of examples 19 to 25). In this example, the notch filter is a physical layer digital notch filter.

Another example (e.g., example 27) relates to a previous example (e.g., any one of examples 19 to 26) or to any other example. In this example, the notch filter is an externally configurable WLAN physical layer notch filter.

An example (e.g., example 28) relates to a method. The method includes determining, for a plurality of frequency ranges of a wireless communication, a plurality of notch filter configurations for a notch filter for filtering communication signals of the wireless communication. The method further includes configuring a database to comprise, for the multiple frequency ranges, the respective notch filter configuration.

Another example (e.g., example 29) relates to a previous example (e.g., example 28). In this example, the wireless communication is a wireless local area network, WLAN, communication.

Another example (e.g., example 30) relates to a previous example (e.g., example 28 or 29). In this example, the multiple frequency ranges are predefined channels in predefined frequency bands for the wireless communication.

Another example (e.g., example 31) relates to a previous example (e.g., any one of examples 28 to 30). In this example, the plurality of notch filter configurations are to filter one or more of spur and narrowband noise caused by the computing platform at respective frequency ranges.

Another example (e.g., example 32) relates to a previous example (e.g., any one of examples 28 to 31). In this example, the notch filter is a physical layer digital notch filter.

Another example (e.g., example 33) relates to a previous example (e.g., any one of examples 28 to 32) or to any other example. In this example, the notch filter is an externally configurable WLAN physical layer notch filter.

An example (e.g., example 34) relates to a method. The method includes measuring, for multiple frequency ranges, a platform noise profile of a computing platform. The method further includes selecting, from a database comprising multiple notch filter configurations for the multiple frequency ranges, a subset of frequency ranges for which the respective platform noise profile exhibits spur or narrowband noise caused by the computing platform. The notch filter is for filtering communication signals of the wireless communication based on notch filter configurations for the subset of frequency ranges.

Another example (e.g., example 35) relates to a previous example (e.g., example 34). In this example, the wireless communication is a wireless local area network, WLAN, communication.

Another example (e.g., example 36) relates to a previous example (e.g., example 34 or 35). In this example, the multiple frequency ranges are predefined channels in predefined frequency bands for the wireless communication.

Another example (e.g., example 37) relates to a previous example (e.g., any one of examples 34 to 36). In this example, the multiple notch filter configurations are configured to filter one or more of the spur and the narrowband noise at the respective frequency range.

Another example (e.g., example 38) relates to a previous example (e.g., any one of examples 34 to 37). In this example, the notch filter is a physical layer digital notch filter.

Another example (e.g., example 39) relates to a previous example (e.g., any one of examples 34 to 38) or to any other example. In this example, the notch filter is an externally configurable WLAN physical layer notch filter.

An example (e.g., example 40) relates to an apparatus comprising interface circuitry, machine-readable instructions, and processing circuitry. The processing circuitry is to execute the machine-readable instructions to measure, for multiple frequency ranges, a platform noise profile of a computing platform. The machine-readable instructions further comprise instructions to select, from a database comprising multiple notch filter configurations for the multiple frequency ranges, a subset of frequency ranges for which the respective platform noise profile exhibits spur or narrowband noise caused by the computing platform. The notch filter is for filtering communication signals of the wireless communication based on notch filter configurations for the subset of frequency ranges.

Another example (e.g., example 41) relates to a previous example (e.g., example 40). In this example, the wireless communication is a wireless local area network, WLAN, communication.

Another example (e.g., example 42) relates to a previous example (e.g., example 40 or 41). In this example, the multiple frequency ranges are predefined channels in predefined frequency bands for the wireless communication.

Another example (e.g., example 43) relates to a previous example (e.g., any one of examples 40 to 42). In this example, the multiple notch filter configurations are to filter one or more of the spur and the narrowband noise at the respective frequency range.

Another example (e.g., example 44) relates to a previous example (e.g., any one of examples 40 to 43). In this example, the notch filter is a physical layer digital notch filter.

Another example (e.g., example 45) relates to a previous example (e.g., any one of examples 40 to 44) or to any other example. In this example, the notch filter is an externally configurable WLAN physical layer notch filter.

An example (e.g., example 46) relates to an apparatus including processor circuitry (or processing circuitry) configured to carry out a method according to a previous example (e.g., any one of examples 19 to 39) or to any other example.

Another example (e.g., example 47) relates to a computer program having a program code for performing the method of a previous example (e.g., any one of examples 19 to 39) or to any other example, when the computer program is executed on a computer, a processor, or a programmable hardware component.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps,-functions,-processes or-operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system. For example, the methods described herein may likewise be carried out by a corresponding apparatus.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. An apparatus comprising interface circuitry, machine-readable instructions, and processing circuitry to execute the machine-readable instructions to:
receive data indicating a frequency range used by a computing platform for wireless communication, wherein the computing platform comprises a notch filter for filtering platform noise from communication signals of the wireless communication;
search a database based on the received data, wherein the database comprises multiple frequency ranges for a respective notch filter configuration; and
if the database comprises a notch filter configuration for the frequency range of the received data, apply the respective notch filter configuration to the notch filter.

2. The apparatus of claim 1, wherein the wireless communication is a wireless local area network, WLAN, communication.

3. The apparatus of claim 2, wherein the machine-readable instructions further comprise instructions to:
send the notch filter configuration to a WLAN driver of the computing platform for applying the respective notch filter configuration to the notch filter.

4. The apparatus of claim 1, wherein the frequency range is one of a plurality of predefined channels in one or more predefined frequency bands for the wireless communication.

5. The apparatus of claim 1, wherein the multiple frequency ranges are predefined channels in predefined frequency bands for the wireless communication.

6. The apparatus of claim 1, wherein the machine-readable instructions further comprise instructions to:
apply the respective notch filter configuration to the notch filter during runtime of the computing platform.

7. The apparatus of claim 1, wherein the respective notch filter configuration is to filter one or more of spur and narrowband noise caused by the computing platform.

8. The apparatus of claim 1, wherein the notch filter is a physical layer digital notch filter.

9. The apparatus of claim 1, wherein the notch filter is an externally configurable WLAN physical layer notch filter.

10. A method comprising:
determining, for a plurality of frequency ranges of a wireless communication, a plurality of notch filter configurations for a notch filter for filtering communication signals of the wireless communication; and
configuring a database to comprise, for the multiple frequency ranges, the respective notch filter configuration.

11. The method of claim 10, wherein the wireless communication is a wireless local area network, WLAN, communication.

12. The method of claim 10, wherein the multiple frequency ranges are predefined channels in predefined frequency bands for the wireless communication.

13. The method of claim 10, wherein the plurality of notch filter configurations are to filter one or more of spur and narrowband noise caused by the computing platform at respective frequency ranges.

14. The method of claim 10, wherein the notch filter is a physical layer digital notch filter.

15. The method of claim 10, wherein the notch filter is an externally configurable WLAN physical layer notch filter.

16. An apparatus comprising interface circuitry, machine-readable instructions, and processing circuitry to execute the machine-readable instructions to:
measure, for multiple frequency ranges, a platform noise profile of a computing platform; and
select, from a database comprising multiple notch filter configurations for the multiple frequency ranges, a subset of frequency ranges for which the respective platform noise profile exhibits spur or narrowband noise caused by the computing platform, wherein the notch filter is for filtering communication signals of the wireless communication based on notch filter configurations for the subset of frequency ranges.

17. The apparatus of claim 16, wherein the wireless communication is a wireless local area network, WLAN, communication.

18. The apparatus of claim 16, wherein the multiple frequency ranges are predefined channels in predefined frequency bands for the wireless communication.

19. The apparatus of claim 16, wherein the multiple notch filter configurations are to filter one or more of the spur and the narrowband noise at the respective frequency range.

20. The apparatus of claim 16, wherein the notch filter is a physical layer digital notch filter.
